(19) United States
(12) Patent Application Publication
(10) Pub. No.: US 2002/0175695 A1
(43) Pub. Date: Nov. 28, 2002

(54) Micro probing techniques for testing electronic assemblies

(76) Inventors: Robert D. Ahmann, Rochester, MN (US); Peter M. Herman, Oronoco, MN (US)

Correspondence Address: Jonar J. Tolentino, DORSEY & WHITNEY LLP, Suite 1500, 50 South Sixth Street, Minneapolis, MN, 55402-1498, US

(21) Appl. No.: 10/103,525

(22) Filed: Mar. 21, 2002

Related U.S. Application Data
(63) Continuation of application No. 08/774,159, filed on Dec. 26, 1996, now abandoned.
(60) Provisional application No. 60/013,753, filed on Mar. 20, 1996.
(60) Provisional application No. 60/009,358, filed on Dec. 29, 1995.
(60) Provisional application No. 60/009,309, filed on Dec. 29, 1995.

(51) Int. Cl. G01R 31/02

(52) U.S. Cl. 324/761

(57) ABSTRACT

The present invention relates to a device testing interface that assists in the testing of fine pitched electronic assemblies. Three embodiments are defined. In the first embodiment, a flex probe comprises a flex circuit with probe tips. The probe tips are attached to the pads of the flex circuit and are coupled with elastomeric springs.

In the second embodiment, a flex probe comprises a flex circuit with conductive elastomeric material attached to probe pads on the flex circuit such that the conductive elastomeric layer is between the flex circuit and the electronic assembly to be tested.

In the third embodiment, a cantilever is formed in a flexible circuit. The flexible circuit device is attached to a non-conductive stiffener layer such that a portion of the cantilever is extending over a probe pin receiving channel in the non-conductive stiffener layer. A probe pin is inserted into the channel and attached to the portion of the cantilever that is extending over the channel. The probe pins are attached to the corresponding test points on the electronic assembly to be tested. Alternatively, as opposed to using a portion of the flexible circuit as a cantilever, a specialized surface mount technology may be used.

### TECHNICAL FIELD

The present invention relates to a probing mechanism that assists in the testing of electronic assemblies. In particular, the present invention relates to an apparatus that provides an interface between the device to be tested and the testing equipment that enables testing of fine pitched electronic assemblies.

### BACKGROUND OF THE INVENTION

During manufacturing, electronic assemblies need to be tested. One device used to test electronic assemblies is called a bed of nails. A bed of nails is an assembly for probing multiple test points of a device under test (“DUT”). It typically consists of a phenolic planar layer with embedded pogo pins corresponding to the test points on the DUT which need to be probed. Pogo pins are devices used to probe electronic assemblies. They consist of conductive spring loaded pins, mounted within barrel shaped tubes. The pins make contact with the device being tested and provide paths for electrical signals to and from the device. The pins are able to retract within the housings to absorb any variations in the “z” axis. Since the pins are mounted in housings (barrel shaped tubes), there are automatic limitations on how close two pins can be together. This limits the use of pogo pins in fine pitched applications.

The device under test is probed by lining up pogo pins in the bed-of-nails with their corresponding test points on the DUT and lowering the bed-of-nails onto the DUT. Tolerances are typically held through mechanical fixturing. Since the device utilizes pogo pins, it is limited by the physical structure of them in its ability to probe fine pitch devices. Today's state-of-the-art capability for pad pitch is around 0.020″ with this technology. Since this device is dependent on pogo pins being embedded in a phenolic layer, its construction is labor intensive and prone to quality and cost problems.

Currently, wafer probes may be used to probe finer pitched electronic assemblies. Each wafer probe consists of cantilevered conductive arms, typically resembling small formed wires. These arms typically extend out from a mounting card and then bend down to meet the appropriate pads of the device under test. Since the arms are conductive, they provide continuity between the pads being tested and any external test equipment. The arms are often bent to meet the test pads, and thus act as springs to absorb any “z” axis variations. Because there are no housings, the pins can be placed in very close proximity, being limited by their mechanical assembly tolerances into a unit.

Another apparatus used to probe finer pitched devices is a membrane probe. A membrane probe is a probe assembly adapted to test an integrated circuit (“IC”) device whose contact pads are deployed in a predetermined pattern in a common plane. The assembly includes a film membrane having a planar dielectric contactor zone and an array of suspension wings radiating from this zone. The wings are clamped at their ends by a mounting ring surrounding a port in a printed circuit board which exposes the contactor zone suspended below the board to the IC device to be tested. Deployed in a matching pattern to the IC contact pads are spring contact fingers which extend from traces running along the wings of the membrane. These spring constant fingers are connected to leads which ultimately connect to electronic test equipment. These wafer probes can be adapted to handle very fine pitch devices.

In today's environment, probing technologies typically become very fragile as they adapt to handle the fine pitch requirements. As such, they are far from ideal for a high volume manufacturing environment. Therefore, it is strongly desired to have a probing technology which can withstand the abuses of a manufacturing environment, yet offer fine pitch capability with long term reliability. Clearly, it is desirable to have a device which is not fragile.

Also, in today's environment, probing technologies typically have to change as the pad pitches get smaller on electronic assemblies. Therefore, if it was desired to test an electronic assembly that had both standard PCB test points and test points on an IC, it is necessary to devise a hybrid device which contains both pogo pins for the PCB test points and wafer or membrane probes for the IC test points. As such, it causes the probing apparatus to get more complex and costly to handle both technologies. Clearly, it is desirable to have one device which can handle both extremes.

The problems with the current technology are five fold and relate to the probing of fine pitched electronic devices and/or assemblies. First, the current primary probing technology (pogo pins in a fixture) does not allow itself to be used on very fine pitch electronic assemblies, unless test pads are provided at a greater pitch. As a result, the primary alternative for very fine pitch applications are wafer probes. However, that technology is susceptible to very stringent mechanical assembly tolerances and is very fragile for manufacturing applications. Therefore, the second problem was to eliminate those concerns. Third, the current primary probing technology (i.e., pogo pins in a fixture, wafer probes, and membrane probes) is manually labor intensive, thus posing potential quality and cost problems. Fourth, the cost of all the current probing technologies (i.e., pogo pins in a fixture, wafer probes, and membrane probes) are cost prohibitive for more complex requirements. Fifth, the turn around times (“TAT”) for complex applications of the current probing technologies (i.e., pogo pins in a fixture, wafer probes, and membrane probes) are extensive. Therefore, an alternative which provides very fine pitch capability, which can be automated, which doesn't have assembly tolerance issues, which is not fragile in a manufacturing environment, and which can be manufactured cost effectively would be very desirable.

### SUMMARY OF THE INVENTION

The present invention relates to a device testing interface that assists in the testing of fine pitched electronic assemblies. Three embodiments are defined. In the first embodiment, a flex probe comprises a flex circuit with probe tips. The flex circuit comprises a plurality of probe pads with a probe land extending from each probe pad. Probe tips are attached to the pads of the flex circuit and are coupled with elastomeric springs.

In the second embodiment, a flex probe comprises a flex circuit with conductive elastomeric material attached to probe pads on the flex circuit such that the conductive elastomeric layer is between the flex circuit and the electronic assembly to be tested. The elastomeric will provide a conductive path between the electronic assembly to be tested and the probe. The elastomeric material will allow the probe to absorb minor variations in the Z axis, such as those which might occur on die, wafers, or other selective electronic assemblies. Conductive lands in the flex circuit will again route the electrical signals to/from the DUT and a connector used for interfacing to electronic test equipment. By using this combination of fabricated probe tips, flex circuit technology, and elastomerics, the probe can be made very robust with respect to fragility. In other words, it can offer the ability to withstand significant abuse in a manufacturing environment.

In the third embodiment of the present invention, a device testing interface comprises a non-conductive stiffener layer, at least one flexible circuit device, and at least one probe pin. The non-conductive stiffener layer has at least one probe pin receiving channel corresponding to a test point location on the electronic assembly to be tested. The non-conductive stiffener layer also supports the flexible circuit device.

The flexible circuit device comprises of a flexible substrate layer and a conductive layer. A cantilever is formed in the flexible substrate layer and the conductive layer. The flexible circuit device is attached to the non-conductive stiffener layer such that a portion of the cantilever is extending over a probe pin receiving channel. A probe pin is inserted into the channel and attached to the portion of the cantilever that is extending over the channel. The probe pins are attached to the corresponding test points on the electronic assembly to be tested and the flex circuit is attached to the testing equipment. The device testing interface enables signals to be communicated to and from the electronic assembly being tested.

In an alternative implementation of the third embodiment, the device testing interface comprises two nonconductive stiffener layers, a flexible circuit, probe pins, and cantilevers designed as a specialized surface mount technology (“SMT”) component. The SMT component will have a conductive cantilever connecting a probe pin to a conductive via in the flexible circuit. The flexible circuit will have flexible substrate layer and a conductive layer. The conductive via is for an electrical connection between the SMT component and the conductive layer of the flexible circuit. This conductive via will provide electrical connection from the probe pin back to the electrical conductors in the flexible circuit. The probe pins are attached to the corresponding test points on the electronic assembly to be tested and the flex circuit is adapted to be attached to the testing equipment. The device testing interface enables signals to be communicated to and from the electronic assembly being tested.

It is the object of this invention to provide an apparatus to assist in the testing of electronic assemblies.

Another object of the present invention is to manufacture the probing mechanism utilizing current printed circuit manufacturing technology, thereby, lowering the cost of manufacturing the probing device and automating certain steps in the production of the device.

It is the further object of this invention that the device be able to handle very fine pitch electronic devices (such as bonding pads on an IC or wafer) in addition to normal fine pitch test pads on selective printed circuit assemblies (such as a flex circuit).

It is a still further object of this invention to have a probing device that can withstand the abuses of a manufacturing environment, yet be affordable.

It is a still further object of this invention that the probing device be able to handle a diversity of devices with the same electronic assembly to be tested.

It is a further object of this invention to have its manufacturing process minimize manual intervention.

It is a further object of this invention to greatly improve the cost and delivery schedules of existing probing technologies to the customer.

### BRIEF DESCRIPTION OF THE DRAWINGS

FIG. 1 is a block diagram illustrating the orientation of the present invention with respect to the test hardware and the testing equipment.

FIG. 2 is a diagram showing test points on a device under test.

FIG. 3 is top view of a flex circuit that is to be tested.

FIG. 4 is a front view of a flex probe of the present invention.

FIG. 5 is a side view of the flex probe of the present invention.

FIG. 6 is a cut-away view of a flex probe of the present invention being applied to test pads of a device under test.

FIG. 7 is a cut-away view of a flex probe of the present invention after application to test pads of a device under test.

FIG. 8 is a diagram illustrating use of a camera to align the flex probe of the present invention to the test pads of the device under test.

FIG. 9 is a top view of an alternative embodiment of the flex probe for testing integrated circuits.

FIG. 10 is a flow chart of the steps involved in manufacturing the flex probe of the present invention.

FIG. 11 is a front view of an alternative embodiment of the flex probe of the present invention.

FIG. 12 is a side view of an alternative embodiment of the flex probe of the present invention.

FIG. 13 is a cut-away view of an alternative embodiment of the flex probe of the present invention being applied to test pads of a device under test.

FIG. 14 is a cut-away view of an alternative embodiment of the flex probe of the present invention after application to test pads of a device under test.

FIG. 15 is a diagram illustrating use of a camera to align the alternative embodiment of the flex probe of the present invention to the test pads of the device under test.

FIG. 16 is a block diagram showing the orientation of the apparatus of the present invention in relation to the test hardware or device under test and the testing equipment used to test the testing hardware.

FIG. 17 shows a cross sectional view of the apparatus of the present invention with a probe pin inserted into a probe pin receiving area or via.

FIG. 18 shows a cross sectional view of the apparatus of the present invention with the probe pin engaging the cantilevered flex circuit assembly.

FIG. 19 shows a bottom view of the flex circuit without the nonconductive stiffener layer.

FIG. 20 shows an alternative embodiment of the present invention using surface mount technology.

FIG. 21 is a block diagram of the manufacturing process to manufacture the apparatus of the present invention.

FIG. 22 is front view of a flex probe of the present invention with probe tips on the cantilevers formed on the flex circuit.

FIG. 23 is a side view of the flex probe of the present invention with probe tips on the cantilevers formed on the flex circuit.

### DETAILED DESCRIPTION OF THE PREFERRED EMBODIMENTS

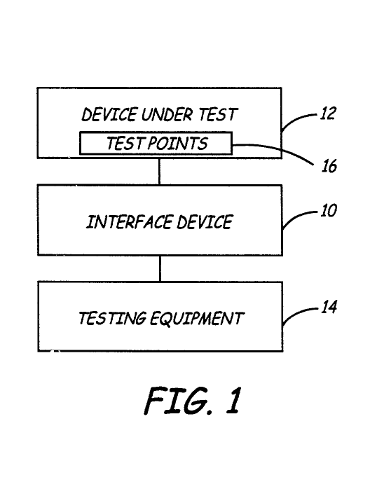

FIG. 1 shows the device testing interface or probing mechanism 10 (also, referred to as “flex probe” or “probe array”) with respect to the electronic assembly 12 being tested (also, referred to as the “device under test” or “test hardware”) and the testing equipment 14. The electronic assembly 12 to be tested may be an integrated circuit (“IC”), a flexible circuit (also referred to as a “flex circuit”), and/or a printed circuit board (“PCB”). A printed circuit board is a planar mechanism consisting of alternating layers of phenolic and etched copper traces. The traces perform the function of interconnecting electronic components placed on the planar mechanism to provide a functional electronic device.

Continuing to refer to FIG. 1, the apparatus of the present invention assists in the testing of electronic assemblies 12. While this apparatus 10 will not perform the tests, it will act as the mechanism for sending and receiving electronic signals from the device under test 12 to the testing equipment 14.

This specification will describe three embodiments of the device testing interface 10 of the present invention: (1) a device testing interface 10 using a flex circuit and probe tips; (2) a device testing interface 10 using a flex circuit and a conductive elastomeric layer; and (3) a device testing interface 10 using a flex circuit with cantilevers on a multi-via substrate. In the first embodiment, the communication between an electronic assembly 12 and the testing equipment 14 will be accomplished through the use of probe tips on a flex circuit which mate with corresponding test points 16 of the electronic assembly 12 to be tested and route the electronic signals to a common connector for direct interfacing to the test hardware 12, thereby, enabling direct interfacing between the test hardware 12 and the testing equipment 14. In the second embodiment, the communication between an electronic assembly 12 and the testing equipment 14 will be accomplished through a conductive elastomeric material which will electrically connect the flexible circuit probe 10 to the DUT 12 and route the electronic signals to a common connector for direct interfacing to the test hardware 12, thereby, enabling direct interfacing between the test hardware 12 and the testing equipment 14. In the third embodiment, the communication between an electronic assembly 12 and the testing equipment 14 will be accomplished through the use of electronic probes which mate with cantilevers of a flexible circuit or SMT device of the device testing interface 10 (which will be described later) and route the electronic signals to a common connector, thereby, enabling direct interfacing between the test hardware 12 and the testing equipment 14.

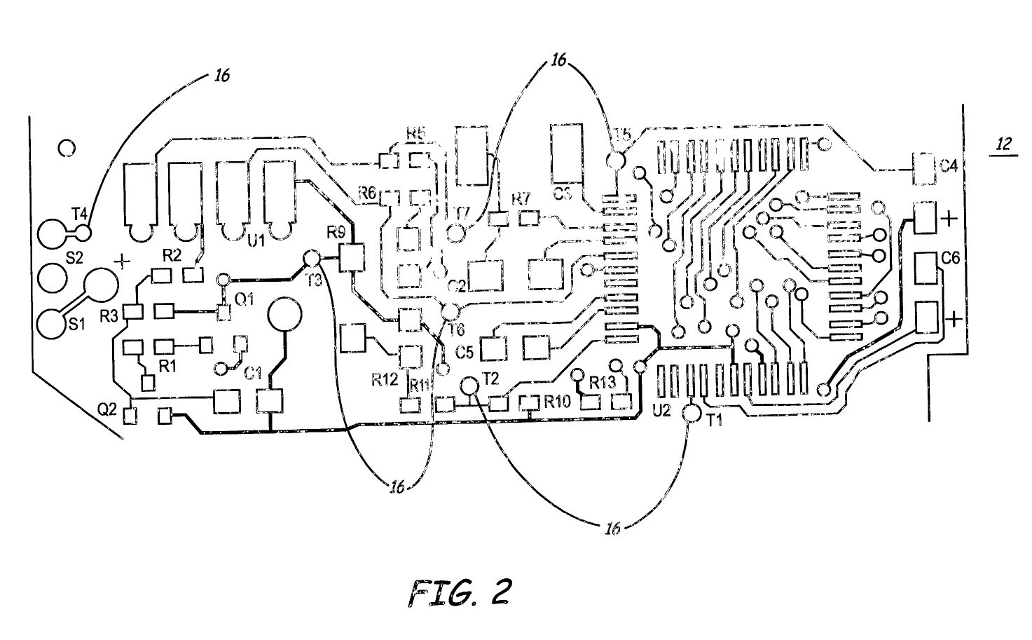

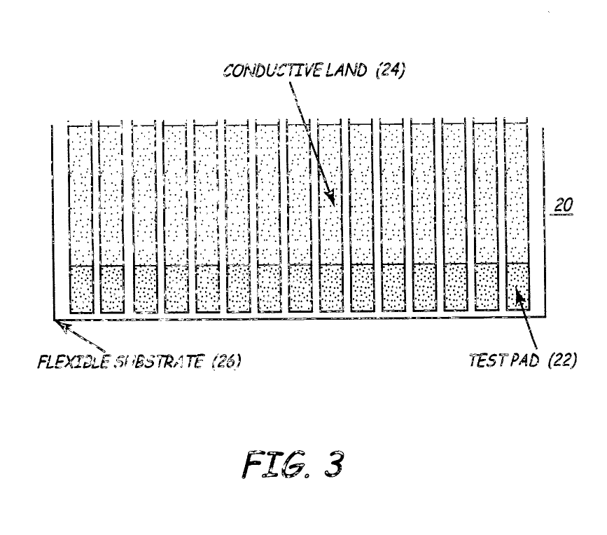

Before describing each of these embodiments, with reference to FIGS. 2 and 3, the electronic assembly 12 to be tested will be described. As shown in FIG. 2, the electronic assembly 12 to be tested has a plurality of test points 16. The test points may be test points on a PCB, an IC, or a flex circuit. These test points 16 may be close together in relation to each other. The closer the test points 16 are to each other the finer the pitch is for the device under test 12. As mentioned above, the present invention may be used to test devices 12 that have a very fine pitch such as bonding pads on an integrated circuit.

FIG. 3 shows a top view of a typical flex circuit 20, which requires fine pitch probing. This flex circuit 20 is representative of the types of circuits that are found within the disk drive industry, where the flex circuit 20 forms a cable connector from the magnetic heads to a PCB. The DUT flex circuit 20 comprises conductive pads 22, conductive lands 24, and a flexible substrate 26. In this case, the head connections are typically made along a row of conductive pads 22 as shown in the diagram. The signals to and from these conductive pads 22 are typically transferred to processing electronics on the DUT flex circuit 20 prior to going through an additional connector to the PCB. These connections are made with conductive lands 24 running throughout the circuit 20. These lands 24 are built upon a flexible substrate 26 to facilitate packaging within the disk drive.

The conductive pads 22 coupled with a PCB connector (not shown) typically act as the test points 16 for electronically testing the flex circuit 20. Historically, pogo pins have been used to probe all these points. However, with the advent of new head technology, the pad pitch has become too small to use this conventional technology. While other applicable probing technologies exist, they are typically either too expensive and/or fragile. In order to solve these and other problems, three embodiments using a flexible circuit as part of a probing mechanism 10 will be described. Flexible circuits may be used to solve this problem of probing fine pitched devices because flexible circuits can be used to provide very fine pitched conductors.

### Embodiment 1—Device Testing Interface Using A Flex Circuit with Probe Tips

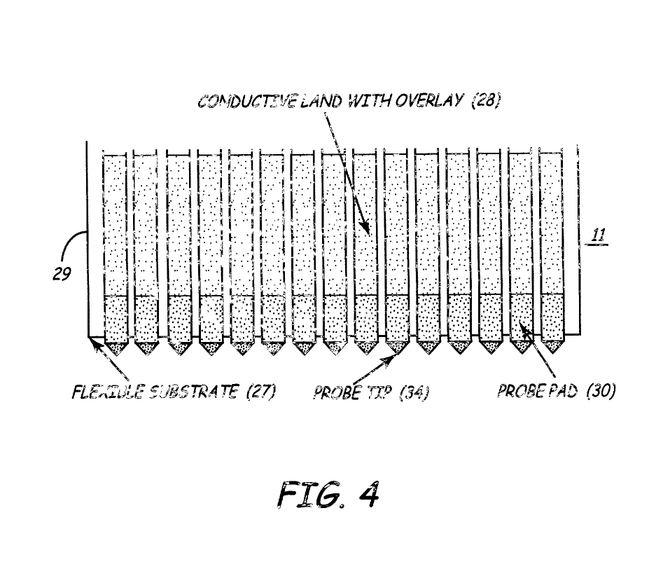

With reference to FIGS. 4-9, the first embodiment 11 (referred to as “flex probe” or “flexible circuit probe device) of the device testing interface 10 using a flexible circuit 29 with a probe tip 34 will be described. FIG. 4 is the front view of a flexible circuit probe device 11 of the present invention comprising a flexible substrate 27, a plurality of conductive probe lands 28, a plurality of conductive probe pads 30, and a plurality of probe tips 34. The flexible substrate 27, the probe lands 28, and the probe pads 30 form the flex circuit 29 for the flex probe 11. The flexible substrate 27 supports the probe lands 28 and probe pads 30. The flexible substrate is formed of a flexible membrane such as mylar, polymid, or polyester.

Continuing to refer to FIG. 4, the pattern of probe lands 28 and probe pads 30 correspond to the DUT flex circuit 20 shown in FIG. 3. The probe tips 34 are connected to the probe pads 30 to facilitate a repeatable connection between the probe pads 30 on the flex circuit probe device 11 and the conductive pads 22 on the DUT 12. The number of probe tips 34 will usually equal the number of test points 16 that need to be tested on the DUT 12. That is, each probe tip 34 will have a corresponding test point 14 on the DUT 12. The probe lands 28 are adapted to be connected to testing equipment 14, thereby, facilitating communication between the device under test 12 and the testing equipment 14.

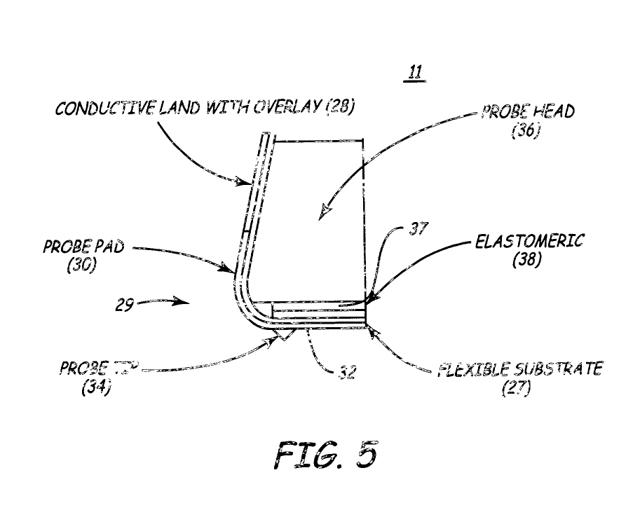

FIG. 5 shows a cross section of the flex circuit probe device 11. As shown in FIG. 5, the flex circuit 29, which comprises the flexible substrate 27, the probe lands 28, and the probe pads 29, is mounted on a rigid probe head 36 which acts as stiffener. The flex circuit 29 is folded back underneath itself on the bottom 37 of the probe head 36 to provide a horizontal surface 32 to be used for attaching a probe tip 34. An elastomeric layer 38 is placed between the portion of the flex circuit 29 that is folded back underneath itself on the bottom 37 of the probe head 36 and the probe head 36. This elastomeric layer 38 is a nonconductive layer. In the preferred embodiment, the elastomeric layer 38 is formed from a non-conductive substance like silicon rubber. This elastomeric layer 38 is paramount in the operation of the flex probe 10 The elastomeric layer 38 acts as a spring constant behind the probe tips 34 to absorb any required variations in the z axis.

In the first embodiment, the flex probe 11 will be constructed from a flex circuit 29 which has pads 30 at locations corresponding to required test points 16 on the DUT 12. On each pad 30 corresponding to a test point 16, a conductive pyramid shaped probe tip 34 will be formed. This probe tip 34 may be formed by plating, by evaporating, or by other processes. These processes will provide a shaped probe tip 34 of sufficient hardness and conductivity. Independent of the process used, the consistent shaping of these probe tips is key to the operability of this probe 10 of the present invention.

Once these probe tips 34 have been formed, they will be the conductive elements which make contact with the DUT 12. The probe tips 34 will be formed from a harder conductive element like beryllium copper or nickel to offer durability. These probe tips 34 will be actuated onto the DUT 12 using an elastomeric backing 38 between the flex circuit 29 and the actuator. The combination of this elastomeric backing 38 and the flexible substrate 27 will allow the probe 11 to absorb minor variations in the Z axis, such as those which might occur on die, wafers, or other selective electronic assemblies. Conductive lands 28 in the flex circuit 29 will then route the electrical signals to/from the DUT 12 and a connector used for interfacing to electronic test equipment.

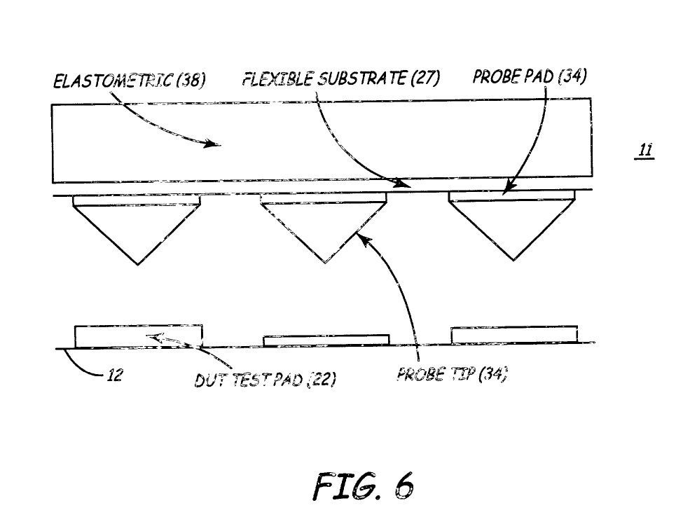

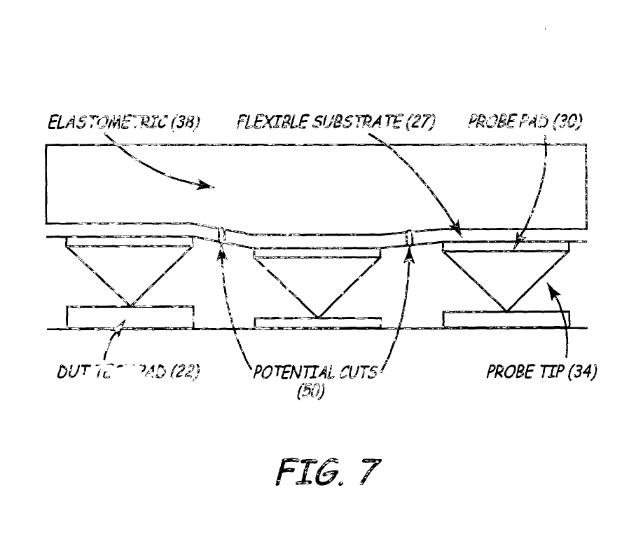

With reference to FIGS. 6 and 7, the ability of the flex probe 11 of the present invention to absorb z axis variation will be described. FIG. 6 shows a front view cross section of the elastomeric interface 38 used in the flex probe 10. The flexible substrate 27 of the flex circuit 29 with its probe pads 30 is seen mounted against the elastomeric interface 38. Mounted on these probe pads 30 are the shaped probe tips 34 with their consistent height. The probe tips 34 could be pyramid or cone shaped depending on the process used to make the probe tip 34. Once each probe tip 34 has been attached to a probe pad 30, the probe tips 34 are ready to be actuated onto the test pads 22 of the DUT 12 where the test pads 22 themselves have some z axis variation. These variations would be typical in any application.

FIG. 7 demonstrates the ability of the elastomeric 38 and flexible substrate 28 to absorb z axis variations once the flex probe 10 is actuated onto the DUT 12. The flex probe device 10 has a limited ability to absorb variations in the z axis. However, the amount of z axis variation the flex probe 10 can absorb is sufficient for many applications such as probing flex circuits or wafers (ICs). This limited ability to absorb variations is why it is so important to have z axis control over the height of the probe tip 34. To the extent height of the probe tip 34 is not controlled (i.e., not uniform), the flex probe 10 could lose its ability to absorb z axis variations given the z axis constraint of the flexible substrate 27 itself.

If z axis variation proves to be a problem in an application, small cuts 50 in the flexible substrate 27 can be made between the probe pads 30. These cuts 50 allow each probe tip 34 to actuate independently, only being constrained by the z axis spring constant interaction of the elastomeric 38 between adjacent probe tips 34. While the cuts 50 do not allow for step function differences between adjacent test pads 30, it provides increased tolerance if required. This cutting would be viewed as an optional process step in the manufacture of the flex probe 11.

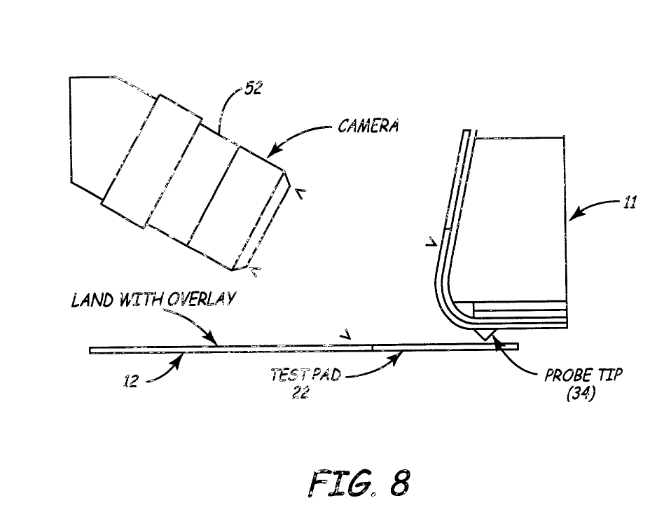

With reference to FIG. 8, the alignment of the flex probe 11 to the DUT 12 will be described. Given the fine pitch of the pads 22 on the DUT 12, some magnification is required to assure proper alignment of the probe pads 30 with test pads 22 on the DUT 12. A magnifying camera 52 may be used to visually align probe pads 30 and test pads 22 of the DUT 12. To use a camera 52 to align the probe pads 30 with the test pads 22, either the flex probe 11 or the DUT 12 must be on some type of mechanical slide. Since the probe tips 34 are centered relative to the probe pads 30, by aligning the probe pads 30 with the test pads 22, it will be guaranteed the probe tip 34 is centered on the test pad 22. Centering each probe tip 34 on its respective probe pad 30 provides maximum adaptability to variations in mechanical tolerances within the system.

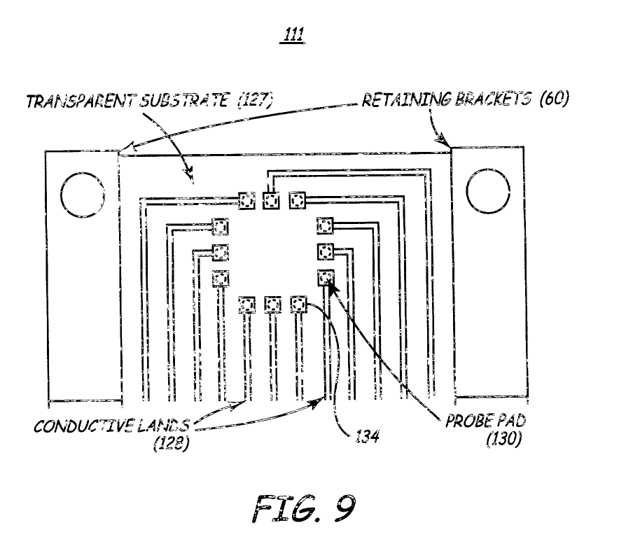

This example of the application of this probing technology has dealt with testing flexible circuits 20 (see FIG. 3). While the testing of flex circuits 20 has its market, a greater opportunity for this technology is in the area of testing electronic die or wafers (IC's). FIG. 9 shows how the flex probe 11 of the present invention may be modified to form a modified flex probe 111 for use in the area of testing electronic die or wafers (IC's). In order to use this modified flex probe 111 to test electronic dies or wafers, the flexible substrate 127 of the flex circuit 129 must be modified. In particular, the flexible substrate 127 used for the flex probe 111 designed for testing electronic dies or wafers should be visually clear. Then, as shown in FIG. 9, conductive probe pads 130 could be etched on the substrate 127 to correspond to locations of wiring pads on the electronic die. These probe pads 130 could then be connected with electronic test equipment using etched lands 128 from themselves back to a connector. As was done with the flex probe 11, probe tips 134 could be constructed on the probe pads 130 to facilitate the probing of the electronic die.

This modified flexible probe 111 could be constrained between two retaining brackets 60 to facilitate its movement when attempting to align the probe pads 130 with the wiring pads of the DUT 12. Since the substrate 127 is clear, the probe tips could be readily aligned with the wiring pads with the assistance of a magnifying camera 52 as in the example above. Once the flex probe 111 was aligned over the DUT 12, it could be actuated onto the DUT 12 as was done in the flex circuit example. It would then be necessary to depress an elastomeric with a stiffener onto the probe tip area. The elastomeric would provide the spring constants to ensure adequate conductivity. How this elastomeric would be applied is dependent on the mechanical design of the specific probe. It could be done in numerous ways. If fiducials could be used for alignment which were away from the wiring pad area, it would allow the elastomeric to reside permanently over the probe tip area and undoubtedly simplify the design of the mechanical probe.

Manufacturing Process

An objective of the present invention is to design a device testing interface 10 which can be manufactured quickly, with high quality and low cost. This is in contrast to many of its alternatives such as wafer probes. Therefore, in order to achieve these objectives, use of existing flex circuit manufacturing processes as much as possible is crucial.

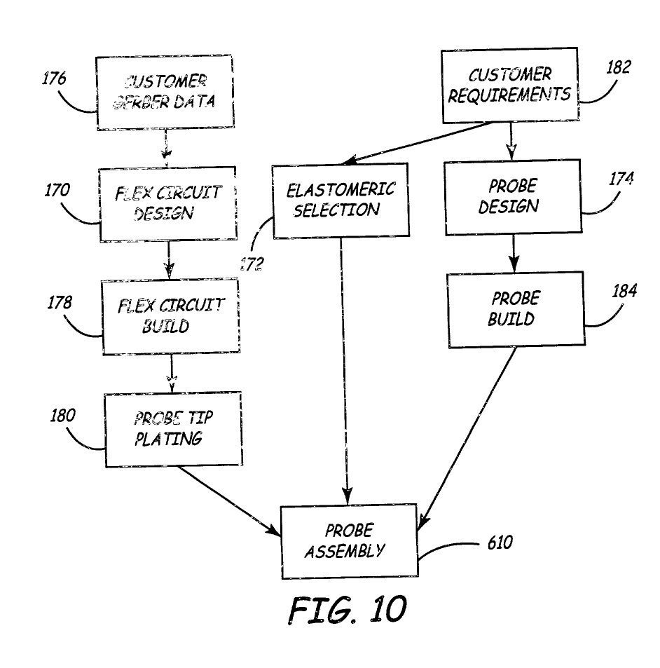

With reference to FIG. 10, the steps for manufacturing the flex probe 11 of the present invention will be described. The manufacturing process is rather simple and is comprised of three parts: flex circuit design 170, elastomeric design 172, and probe design 174. First, the flex circuit design is based on the customer's Gerber data of the device requiring testing. Gerber data or Gerber plots are the final output of a printed circuit physical design software tool. These documents detail the physical characteristics of each layer of a printed circuit assembly, whether it be a board or a flex circuit. This data allows the manufacturer of the printed circuit device to physically make each layer and bond them together into a final assembly. It is effectively the blueprint document for the printed circuit.

Once the flex circuit 29 is designed based on the Gerber data, at step 178 and 180, the flex circuit 29 is built and the probe tips 34 plated on. Steps 178 and 180 could potentially all be done at the flex circuit vendor.

Next, at steps 182, 174, and 184, based on the customer requirements, a mechanical probe head 36 is designed and built. Likewise, based on the customer's need for a maximum allowable force on the DUT 12, an elastomeric 38 is chosen. Once all these elements are available, the flex circuit 29, the elastomeric 38 and the mechanical probe can be assembled into a final mechanical probe assembly. As such, this is a relatively simple manufacturing process, requiring little manual labor. These steps are also applicable apply to the modified flex probe 111.

Existing printed circuit board technology is used in the fabrication of the flex circuit 29 and ultimately the application of the probe tips 34. While the initial prototypes will utilize a plating process to develop the pyramid shaped probe tips, this process can ultimately be embedded in the flex circuit process. Once the probe tips 34 are applied on the flex circuit 29, some minor manual intervention would be required to assemble this probe element with its elastomeric backing and the mechanical actuator. However, this manual operation is far less sensitive to potential problems than what transpires in the manufacturing processes of today's other probing technologies. These same steps are applicable for manufacturing flex probe 111, except that a clear flex substrate 127 must be used.

### Embodiment 2—Device Testing Interface Using A Flex Circuit with Conductive Elastomeric

The flex circuit 20 shown in FIG. 3 will again be used as an example of circuitry requiring fine pitch probing for this methodology. As in the first method, we will also use a flexible circuit 29 for the probe. In contrast to the first method where a non-conductive elastomeric 38 was used to provide a spring constant for the plated probe, the flex probe 210 of the second embodiment uses a conductive elastomeric 238 between the flex circuit 229 and the DUT 12.

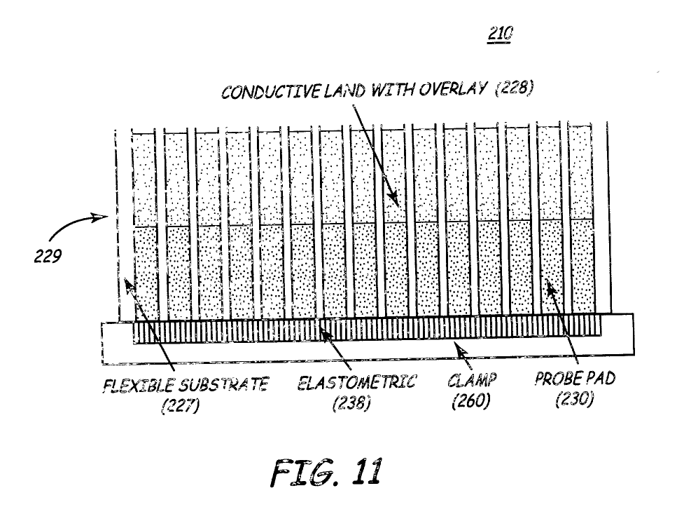

With reference to FIGS. 11-15, the second embodiment 210 (also referred to as “flex probe” or “flexible circuit probe device”) of the device testing interface 10 using a flexible circuit 229 with a conductive elastomeric layer 238 will be described. FIG. 11 is the front view of a flexible circuit probe device 210 of the present invention comprising a flexible substrate 227, a plurality of conductive probe lands 228, a plurality of conductive probe pads 230, a conductive elastomeric layer 238, and a clamp 260. The flexible substrate 227, the probe lands 228, and the probe pads 230 form the flex circuit 229 for the flex probe 10. The flexible substrate 227 supports the probe lands 228 and probe pads 230. The flexible substrate is formed of a flexible membrane such as mylar, polymid, or polyester.

Continuing to refer to FIG. 11, the pattern of probe lands 228 and probe pads 230 correspond to the DUT flex circuit 20 shown in FIG. 3. The conductive elastomeric layer 238 is connected to the probe pads 230 to facilitate a repeatable connection between the probe pads 230 on the flex circuit probe device 210 and the conductive pads 22 on the DUT 12. The conductive elastomeric 138 is attached to the flex probe 210 using a mechanical clamp. Other methods of attachment are also possible, such as bonding. The probe lands 228 are adapted to be connected to testing equipment 14, thereby, facilitating communication between the device under test 12 and the testing equipment 14.

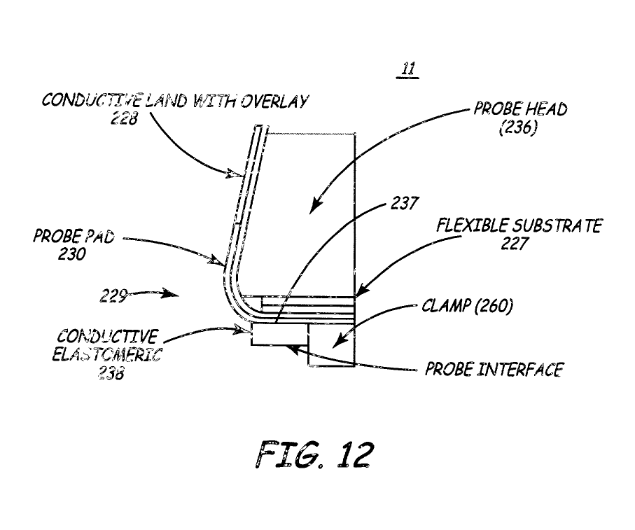

FIG. 12 shows a cross section of the flex circuit probe device 210. As shown in FIG. 12, the flex circuit 229, which comprises the flexible substrate 227, the probe lands 228, and the probe pads 230, is mounted on a rigid probe head 236 which acts as stiffener. The flex circuit 229 is folded back underneath itself on the bottom 237 of the probe head 236 to provide a horizontal surface 232 to be used for a probe interface (i.e., attaching the elastomeric layer 238 to the flex circuit 229). The clamp 260 is mounted behind this surface used as a probe interface.

The conductive elastomeric itself is commercially available from Shin-Etsu Polymer America, Inc. Shin-Etsu sells three types of conductive elastomeric that may be used with the present invention: (1) MT type; (2) GBM type; and (3) GAF type. In the preferred embodiment, the MT type is used. However, the type of conductive elastomeric required is dependent on the specifics of the application. The material itself typically consists of a silicon rubber membrane of varying thickness. Impregnated into the silicon rubber sheet are typically small conductive wires. These wires are placed vertically and thus permit conductivity in the z axis but not in the x and y. They are on the order of 1-2 mils in diameter and can be randomly distributed or placed in an orthogonal matrix, dependent on the type of material used. The silicon rubber acts as a spring to absorb any variations in the z dimension but yet maintains conductivity.

Continuing to refer to FIG. 12, the flex circuit 229 is folded back underneath itself on the bottom 237 of the probe head 236 with a conductive elastomeric material 238 clamped 260 onto the probe pads 230. The bottom of the conductive elastomeric 238 forms the probe interface which is put in contact with the DUT 12. This elastomeric layer 238 is paramount in the operation of the probe 210. It not only acts as the conductor between the DUT 12 and the probe pads 230, but it is also a spring constant to absorb any required variations in the z axis.

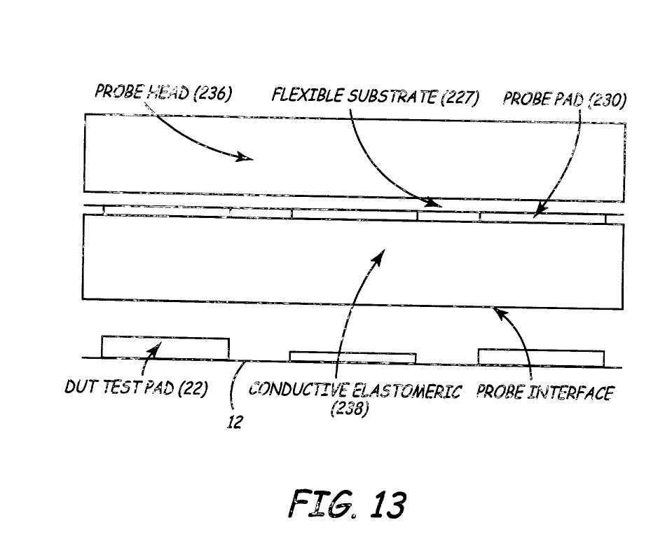

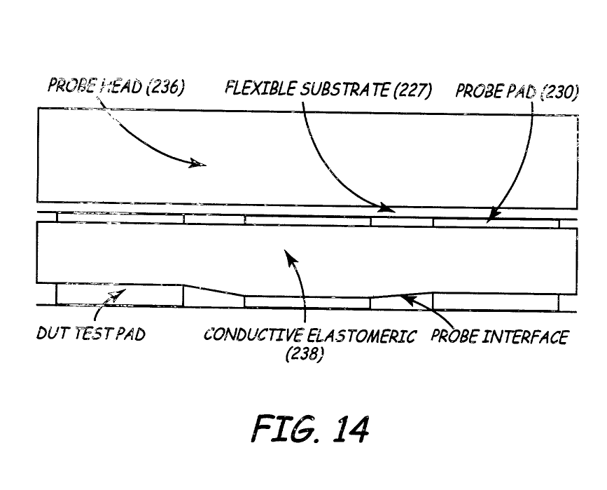

With reference to FIGS. 13 and 14, the ability of the flex probe 210 of the present invention to absorb z axis variation will be described. FIG. 13 shows a front view cross section of the elastomeric interface 238 used in the flex probe 210. The flexible substrate 227 of the flex circuit 229 with its probe pads 230 is seen mounted against the rigid probe head 236. The conductive elastomeric 238 is clamped onto the probe pads 230. The conductive elastomeric 238 has its conductive wires in a vertical orientation, extending down from the probe pads 230 towards the test pads 22 on the DUT 12. The bottom of this elastomeric forms the probe interface. This probe interface is ready to be actuated onto the test pads 22 of the DUT 12 where the test pads 22 themselves have some z axis variation. These variations would be typical in any application.

FIG. 14 demonstrates the ability of the elastomeric 238 to absorb z axis variations once the flex probe 210 is actuated onto the DUT 12. The flex probe device 210 has a limited ability to absorb variations in the z axis. However, the amount of z axis variation the flex probe 210 can absorb is sufficient for many applications such as probing flex circuits, printed circuit boards, or wafers (ICs).

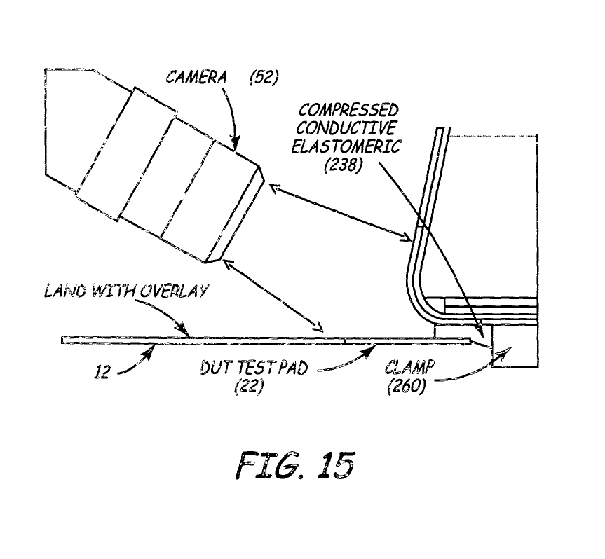

With reference to FIG. 15, the alignment of the flex probe 210 to the DUT 12 will be described. Given the fine pitch of the pads 22, some magnification is required to assure proper alignment of the probe pads 230 with test pads 22 on the DUT 12. A magnifying camera 52 may be used to visually align probe pads 230 and test pads 22 of the DUT 12. To use a camera 52 to align the probe pads 230 with the test pads 22, either the flex probe 10 or the DUT 12 must be on some type of mechanical slide. With the appropriate conductive elastomeric 238, there will be numerous conductors across the width of a probe pad 230. This will assure conductivity between the probe pad 230 and the DUT test pad 22 provided there is a semblance of visual alignment between them.

The flex probe 210 is manufactured using a manufacturing process similar to the manufacturing process described for manufacturing the first embodiment as shown in FIG. 10. As with the manufacturing process of the first embodiment, the manufacturing process for the second embodiment is comprised of three parts: flex circuit design, elastomeric design, and probe design. The flex circuit 229 and the probe head 236 are designed and fabricated as described with reference to the first embodiment. However, with respect to the elastomeric design, unlike the first embodiment, a conductive elastomeric 238 (as opposed to a nonconductive elastomeric) must be selected for flex probe 210. The conductive elastomeric 238 is then mechanically attached to the flex circuit 229. Since the conductive elastomeric 238 is a commercially available product, this overall assembly process is very simple.

### Embodiment 3—Device Testing Interface 10 Using a Flex Circuit With Cantilevers On a Multi-Via Substrate

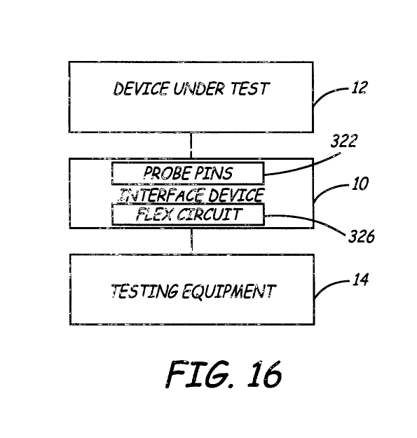

FIG. 16 is a block diagram of the third embodiment of the device testing interface or probe array 310 connected to the electronic assembly 12 being tested (also, referred to as the “device under test” or “test hardware”) and the testing equipment 14. Continuing to refer to FIG. 16, the third embodiment of the probe array 310 communication between an electronic assembly 12 and the testing equipment 14 will be accomplished through the use of electronic probes 322 which mate with a flexible circuit device 326 of the device testing interface 310 and route the electronic signals to a common connector, thereby, enabling direct interfacing between the test hardware 12 and the testing equipment 14.

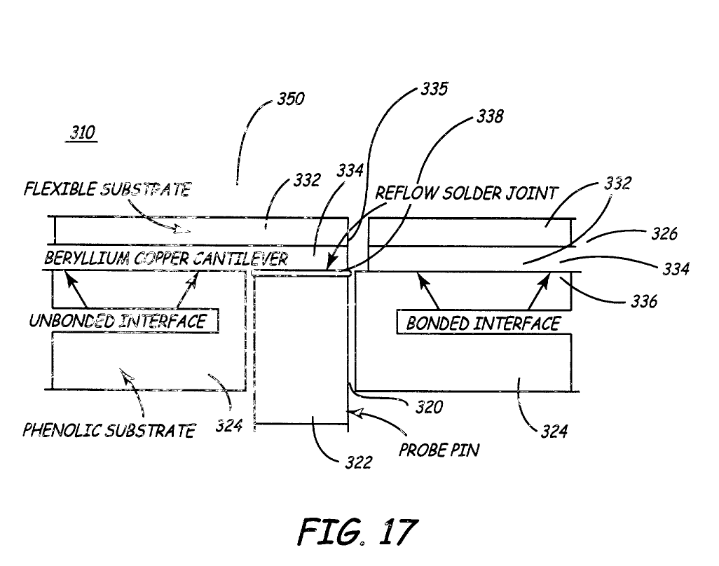

With reference to FIGS. 17-20, the third embodiment 310 of the device testing interface 10 will be described. FIG. 17 shows a cross sectional view of the probe array 310 across a via 320 (which is pathway or pass through hole for the probe pin 322). The probe array 310 comprises a non-conductive stiffener layer 324, at least one flexible circuit 326, and at least one probe pin 322. The non-conductive stiffener layer 324 does not conduct electricity. This layer 324 supports the flexible circuit 326. Also, probe pin receiving channels or vias 320 are formed in this layer 324 to receive a probe pin 322. This layer 324 may be formed using a phenolic element, delron, or some other non-conductive stiffener. In the preferred embodiment, a phenolic element is used to form the non-conductive stiffener layer 324.

The vias or probe pin receiving channels 320 are formed in the non-conductive stiffener layer 324 by drilling holes in the layer 324. The positioning of a channel 320 on the non-conductive stiffener layer 324 is based on the location of the corresponding test point 16 on the device to be tested 12. The number of probe pin receiving channels 320 will be equal to the number of test points 16 on the device to be tested 12.

Continuing to refer to FIG. 17, the flexible circuit device 326 will be described. The flexible circuit device 326 in this example is comprised of two layers: the flexible substrate layer 332 and the conductive layer 334. The flexible substrate layer 332 is formed using mylar, polymid, polyester, or the like.

The conductive layers 334 of this flexible circuit device 326 will be formed using beryllium copper, which is conductive, but at the same time has a higher spring constant than traditional copper. This spring constant will be paramount in providing a spring-loaded force to every probe pin 322 which connects with a test point 16 on the DUT 12. This spring-loaded force will be provided in one of two ways. First, by designing a cantilevered element using beryllium copper into the flex circuit device 326 for each and every probe pin 322 that is required to test the DUT 12. Second, by using a beryllium copper cantilever designed using a specialized surface mount technology component (as will be described later with reference to the alternative implementation of the third embodiment). The needs of the design will determine which of the two ways should be implemented. It should be noted that a design may use both methods.

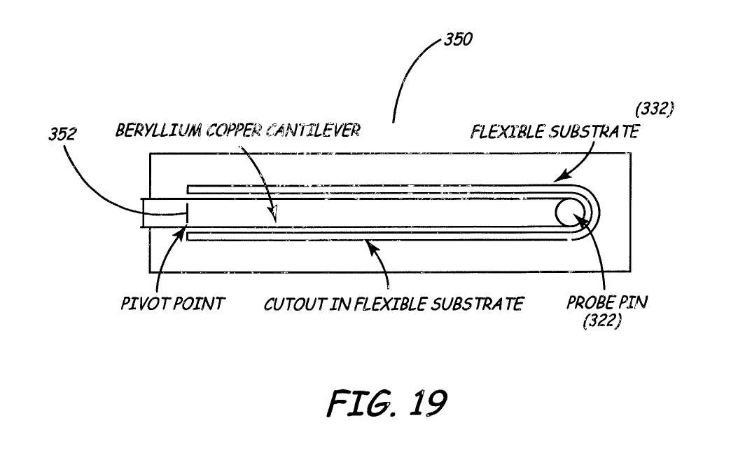

The conductive layer 334, which is formed using a single layer of beryllium copper, is coupled with the flexible substrate layer 332 to provide both the cantilever spring and the conductive land mechanism for the probe array 310. FIG. 19, which is a bottom view of the flexible circuit device 326 without the nonconductive stiffener layer 324 in place, shows the cantilever portion 350 of the flexible circuit device 326. Continuing to refer to FIG. 19, the etched cantilever 350 is formed by cutting the flexible substrate 332 around it, thereby, allowing it to have vertical motion beyond the pivot point 352. The probe pin 322 is shown at the end of the cantilever 350. The spring constant on the probe pin 322 can be accurately controlled by the design of the cantilever 350 (length, height, and width). This flexible circuit device 326 is placed on a non-conductive stiffener layer 324, such that an end 335 of the cantilever 350 is over a corresponding probe pin receiving channel or via 320 in the non-conductive stiffener layer 324. Once the cantilever 350 is positioned properly over the via 320, the probe pin 322 which is inserted into the via 320 can be attached to the cantilever 350.

Prior to the flex circuit device 326 being aligned and placed on the nonconductive stiffener layer 324, a bonding agent 336 is selectively applied on the flex circuit 326 in areas other than the area forming the cantilever 350. This selective application of a bonding agent allows the cantilever 350 to act as a spring for a probe pin 322 which is placed in the via 320 of the nonconductive stiffener layer 324 from the bottom and reflow soldered 338 to the conductive layer 334 of the cantilever 350. FIG. 17 shows this arrangement where the part of the flexible circuit device 326 which is not a cantilever 350 is bonded to the nonconductive stiffener layer 324 (e.g., phenolic substrate) and the cantilever 350 is free to spring back as pressure is applied from the probe pin 322 after being actuated onto the DUT 12.

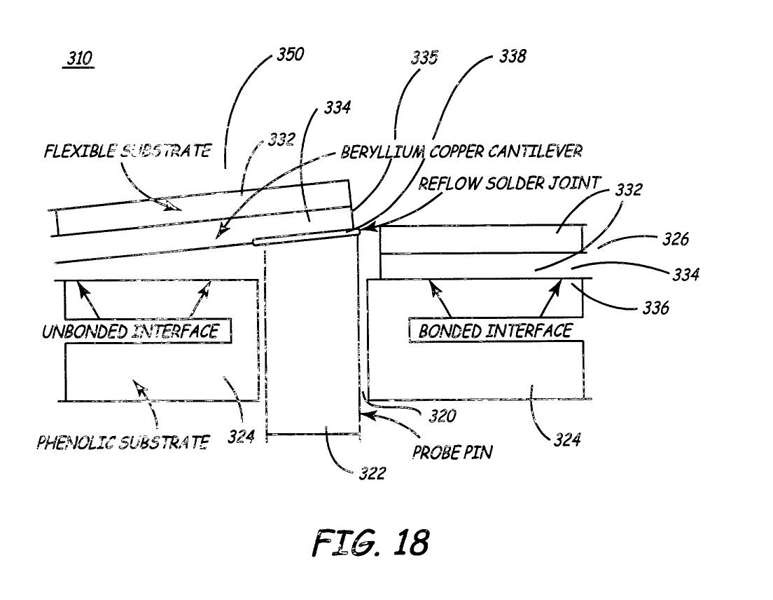

FIG. 18 subsequently shows a representation of the cantilever 350 having sprung back with the probe pin 322 having been actuated onto the DUT 12. It should be pointed out the thickness' of the individual elements are representative only. Nominally, the actual thickness of the flexible substrate 332 is around 1 mil or one thousandth of an inch (0.001 inch). The thickness of the nonconductive stiffener layer 324 is nominally around 62 mils (0.062 inches), the thickness of a standard PCB. However, the nonconductive stiffener layer 324 can be thicker or thinner depending on the application. The conductive layer 334 may range between 1 and 5 mils (0.001.005 inches) inclusive.

Next, the flex circuit 326 will be placed on the nonconductive stiffener layer 324 with the very end of each cantilever 350 corresponding to a hole or via 320 that is drilled into the nonconductive stiffener layer 324. It should be noted that the number of cantilevers 350 will equal the number of probe pin receiving channels 320, which in turn equals the number of test points 16 that will be tested on the test hardware 12. A pin 322 will be placed through this hole 320 and connected to the cantilever 334 with a reflow solder 338 process. This cantilever 350 will not only provide the required spring constant for each probe pin 322, but also act as its conductor to carry electrical signals to and from the connector (not shown) on the end of the flex circuit 326. This connector will be adapted to be connected to the testing equipment 14, thereby, facilitating communication between the testing equipment 14 and the device under test 12. The hole in the phenolic layer(s) will act as a guide for the probe pin 322. The cantilevers' 350 spring constant can be controlled by the thickness of the copper, coupled with its length and width. For the flex circuit 326, the cantilevers 350 are formed by cutting away the flexible substrate 32 surrounding the required length of a copper land (see FIG. 5).

The probe pin 322 ultimately extends through a via 320 in the nonconductive stiffener layer 324. The via 320 through the nonconductive stiffener layer 24 acts as a guide for the pin 322 relative to its corresponding test point 16 on the DUT 12. It can be seen in FIG. 18, the spring force on the probe pin 322 is not purely a vertical component, it also has a lateral component. Therefore, the tolerance of the via 320 relative to the diameter of the probe pin 322 is critical to maintain its placement accuracy on the DUT 12 and to avoid binding of the probe pin 22.

In operation, each probe pin 322 of the device testing interface 310 is connected to a corresponding test point 16 on the device under test 12. The testing equipment 14 is connected to the conductive layer 334 (which acts as the conductive land mechanism) of flexible circuit device 326 (directly or through connectors). Signals are communicated to and from the device under test 12 through the probe pins 322 and the conductive layer 334 on the cantilever 350 and the noncantilevered portion of the conductive layer 334 of the flexible circuit device 326. The probing mechanism 310 of the present invention, thereby, (1) enables a user to cost effectively test electronic assemblies, (2) provides the user with the capability to probe very fine pitch devices (IC's), (3) provides the user with the capability to handle a diversity of devices with the same fixture. While there are mechanisms on the market today for probing any type of electronic device, none can offer all the desired features in one mechanism.

Alternative Implementation of the Third Embodiment

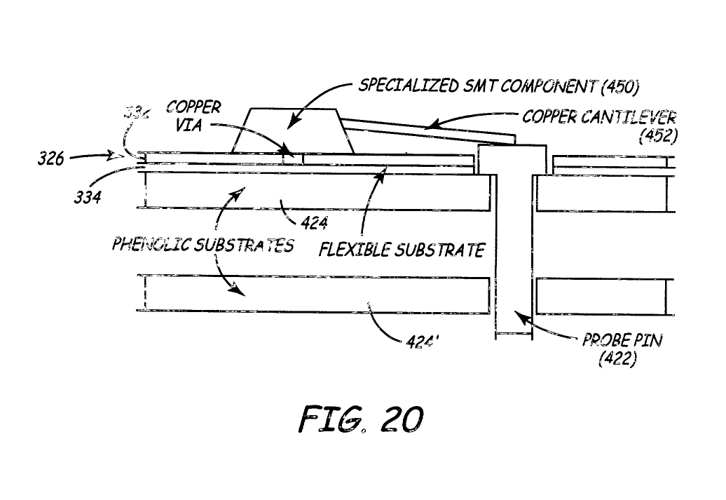

With reference to FIG. 20, an alternative implementation of the third embodiment of the probe array 310 will be described. In this implementation, two nonconductive stiffener layer 424, 424′ are used to provide a better linear guide for the probe pin 422. This characteristic would typically be necessary for larger pitch applications. In this instance, as opposed to using a portion of the flexible circuit device 326 as a cantilever element 350, a specialized surface mount technology 450 (“SMT”) will be used. SMT 450 is the prevalent technology in the manufacturing of printed circuit boards today. It involves the use of electrical and electronic components which have been greatly reduced in size. These components do not have conventional pins which protrude through the surface of the PCB assembly, but rather pins which have been formed to sit on the surface of the PCB assembly. By using this technology, substantial savings in the overall size of the of the PCB assembly can be achieved.

As shown in FIG. 20, the SMT component 450 will have a beryllium copper cantilever 452 connecting the probe pin 424 to a copper via 456 in the flexible circuit layer 326. The flexible circuit layer 326 will have flexible substrate layer 332 and a conductive layer 334. The conductive via or copper via 456 is for an electrical connection between the SMT component 450 and the conductive layer 334 of the flexible circuit layer 326. This copper via 456 will subsequently provide electrical connection from the nail headed probe pin 422 back to the electrical conductors 334 in the flexible circuit layer 326. In this embodiment, no solder connection exists. This configuration will typically be used when two different spring forces are required which are incompatible with the beryllium copper thickness of the flexible circuit layer 326. In any application, permutations of the two embodiments may exist.

Although the SMT component 450 with the cantilever is described in conjunction with the two nonconductive stiffener layer embodiment, this SMT component may be used in the one nonconductive layer embodiment described with reference to FIG. 17.

Normal minimum via diameters in a PCB are 10 mils. Therefore, this technology is easily applicable to the testing of the smallest “packaged” electronic components today. Whereas pogo pins, are limited to about a 20 mil pitch today. This ability to test finer pitched elements is directly attributable to the fact the phenolic substrate via takes the place of the nonfunctional barrel within a pogo pin. With special processing, the minimum diameter via can be reduced to at least 5 mils (if not smaller), which makes this technology also applicable for the direct testing of integrated circuit die.

Manufacturing Process

An objective of this invention is to obtain a probe array 10 which can be manufactured quickly, with high quality and low cost. This is in stark contrast to a classical bed-of-nails. Therefore, in order to meet these objectives, the ability to utilize existing PCB manufacturing processes as much as possible is crucial.

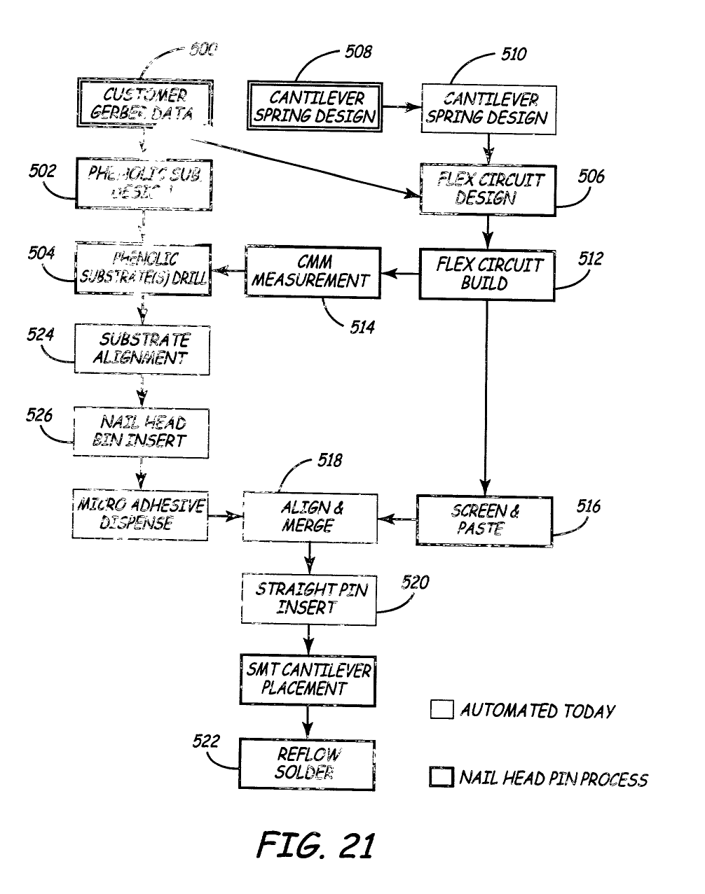

With reference to FIG. 21, the manufacturing process for making a probe array 10 will be described. Those process steps which have an automated solution today are identified with gray cross hatch lines. Those process steps which require an automated solution are shown in darker gray shading. The process steps which are optional depending on the implementation (straight pin vs. nail head pin) are shown with dashed line boxes. As such, it can be seen the process would already be highly automated. That is, either have software automation (i.e., automatic design S/W) or direct hardware automation (reflow ovens, screeners, etc.) available for supporting the process. Thus a manufacturing process would be available immediately with a high degree of automation and a totally automated solution could be readily defined. This facilitates the goals of time, cost, and quality optimization.

Assuming the use of straight pins, the manufacturing process itself starts, at step 500, with the customer supplying Gerber data or Gerber plots of the device requiring testing, in addition to other special requirements such as the required spring force on the test pins. Gerber Plots are the final output of a printed circuit physical design software tool. These documents detail the physical characteristics of each layer of a printed circuit assembly, whether it be a board or a flex circuit. This allows the manufacturer of the printed circuit device to physically make each layer and bond them together into a final assembly. It is effectively the blueprint document for the printed circuit.

The Gerber data is used to define the placement of the vias 320 in the phenolic substrate(s) 324 (step 502) coupled with the definition of DUT test point locations 16 required for the flex circuit physical design (step 506). Prior to doing the actual physical design of the flex circuit 326, at step 508, the customer also supplies requirements for spring force on each test point 16. This information determines the physical design requirements for the cantilevers (step 510) on the flex circuit 326 or for the cantilevers 452 on the specialized SMT components 450. This process will be manually determined and fed into the flex circuit physical design. However, this process may be automated with computer software, and this software would interact with the flex circuit physical design computer software.

Once the physical design of the flex circuit 326 is complete, the flex circuit 326 itself will be built (step 512) using existing processes available today. When the flex circuit 326 is available, at step 514, a CMM (coordinate measuring machine) will be used to measure the actual locations of all the future probe pins 322. This measurement information, combined with the original Gerber data will then be used, at step 504, to drill the phenolic substrate 324. Ultimately, the CMM step will not be necessary, and drilling can proceed directly from the Gerber data. However, until accuracies can be consistently met through the Gerber data alone, the CMM process step will be performed.

At step 516, the flex circuit 326 is now ready for screening and pasting. The screening and pasting steps are done to apply solder paste on the areas where the probe pins 322 will ultimately have to be located and to apply a coating to prevent solder adhesion on any other area of the copper traces. With the completion of screening and pasting, an adhesive will be selectively applied on the phenolic substrate to adhere the flex circuit 326 to the nonconductive stiffener layer 324. This step may be performed by an automated micro adhesive dispenser on locations other than where the cantilevers reside. With the adhesive on the phenolic substrate, at step 518, the flex circuit 326 will now be aligned and merged with it. Next, at step 520, the probe pins 322 will be placed in their respective vias 320. Both these steps may be automated. Finally, at step 522, the probe assembly will be reflow soldered to adhere the probe pins 322 to their respective cantilevers 50.

In the case of the nail head pins 422 (used in the alternative embodiment), two substrates 424, 424′ will probably be utilized to facilitate operational alignment of the pins 422. This use of two substrates requires the two substrates to be separated by some type of stand-off and aligned following being drilled (steps 204 and 224). The nail head pins 122 are inserted at this point to await placement of either the flex circuit and/or the SMT cantilever components to act as their conductive spring. Otherwise a similar process to the one described is used. The exact process however, is be dependent on the specific permutation of the described concepts (i.e. straight, nail head, SMT cantilever, flex cantilever, etc.).

This manufacturing process involves little or no manual intervention. Ideally, a probe 10 array using this technology can be fabricated with existing PCB technology. This fabrication includes the placement and drilling of the phenolic layer(s), the fabrication of the flex circuit containing the conductive cantilevers, and the reflow solder process. The reflow solder process is used to connect the probe pin to the conductive cantilever in the case of a straight probe pin (no nail head) and to connect the specialized SMT cantilever components to the flex in cases they are required.

Also, this manufacturing process greatly improves the cost and delivery schedules of existing probing technologies to the customer. Using the manufacturing process described with reference to FIG. 21, a probe array can be generated very quickly and very affordably. It is the intent of this invention to obtain a 5× improvement over today's technology.

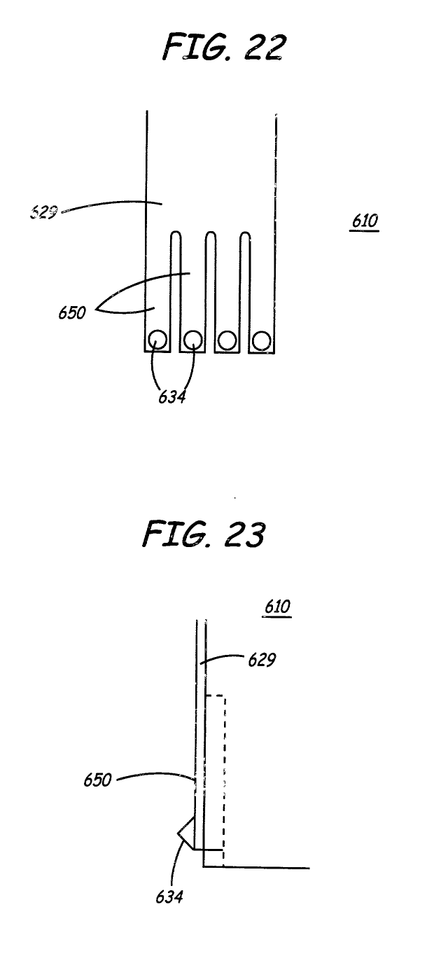

While preferred embodiments of the present invention have been described, it should be appreciated that various modifications may be made by those skilled in the art without departing from the spirit and scope of the present invention. For instance, various aspects of the embodiments may be combined to form another flex probe. For instance, FIGS. 22 and 23 show a flex probe 610 that combines aspects of the first and third embodiments. Flex probe 610 comprises a flex circuit 629 with a plurality of cantilevers 650 formed on the flex circuit 629. At the end of each cantilever 650, a probe tip 634 is formed. This type of flex probe 610 may be used to test magneto-resistive (“MR”) heads in a head stack assembly. Accordingly, reference should be made to the claims to determine the scope of the present invention.

What is claimed is:

1. A flexible probe, comprising:
(a) a flexible circuit having at least one probe pad; and
(b) a probe tip attached to the at least one probe pad.

2. The probe of claim 1, further comprising a stiffener to which the flexible circuit is attached.

3. The probe of claim 2, wherein an elastomeric layer is interposed between the flexible circuit and the stiffener.

4. The probe of claim 3, wherein the flexible circuit comprises a flexible substrate which supports the at least one probe pad.

5. The probe of claim 4, wherein the flexible substrate comprises a plurality of probe pads.

6. The probe of claim 5, further comprising a probe land extending from each of the plurality probe pads.

7. The probe of claim 6, wherein the flexible substrate comprises a cut between each probe pad.

8. The probe of claim 1, wherein the flexible circuit comprises a clear flexible substrate.

9. The probe of claim 1, wherein the number of probe pads with probe tips on a flex circuit equal the number of test points to be tested on a device under test.

10. The probe of claim 1, wherein each of the probe tips are equal in height.

11. The probe of claim 1, wherein each of the probe tips has a pyramidal shape.

12. The probe of claim 1, wherein each of the probe tips has a conical shape.

13. A device testing interface for testing fine pitched electronic assemblies, comprising:
(a) means for connecting to a device under test; and
(b) means for transmitting signals to and from the device under test.

14. The device of claim 13, wherein the means for connecting to a device under test comprises conductive means adapted to be actuated onto a device under test.

15. A method for interfacing with a device under test, comprising the steps of:
(a) mating each probe tip formed on a probe pad on a flex circuit with a corresponding test point on a device under test; and
(b) adapting each probe land extending from a probe pad for connection with the testing equipment, whereby, the testing equipment may communicate with the device under test.

16. The method of claim 15, wherein step of connecting the flex circuit comprises the step of aligning each probe pad with a corresponding test point.

17. A flexible probe, comprising:
(a) a flexible circuit having at least one probe pad; and
(b) a conductive elastomeric layer attached to the at least one probe pad of the flexible circuit.

18. The probe of claim 17, further comprising a stiffener to which the flexible circuit is attached.

19. The probe of claim 17, further comprising a clamp to attach the conductive elastomeric layer to the flexible circuit.

20. A device testing interface for testing a fine pitched electronic assembly, the interface comprising:
(a) a non-conductive stiffener layer having at least one probe pin receiving channel corresponding to a test point location on a test hardware;
(b) a flexible circuit device having a conductive layer, the flexible circuit device attached to the nonconductive stiffener layer; and
(c) a cantilever formed in the flexible circuit device, a portion of the cantilever extending over the probe pin receiving channel.

21. The device of claim 20, further comprising a probe pin attached to the portion of the cantilever extending over the probe pin receiving channel.

22. The device of claim 20, wherein the conductive layer has a spring constant for providing a spring loaded force for every probe pin located in a probe pin receiving channel which connects with a test point on the test hardware.

23. The device of claim 22, wherein the conductive layer is beryllium copper.

24. The device of claim 20, wherein a cantilever is formed for each test point on the test hardware.

25. A device testing interface adapted to be connected to test hardware and testing equipment, the interface comprising:
(a) two non-conductive stiffener layers each having at least one probe pin receiving channel corresponding to a test point location on the test hardware;
(b) a flexible circuit comprising a flexible substrate and a conductive layer, wherein the flexible circuit is attached to one of the two nonconductive stiffener layers; and
(c) at least one surface mount technology device is attached to the flexible substrate with a cantilever extending from the surface mount technology to a probe pin; and
(d) a via from the conductive layer to the surface mount technology device.

26. The device of claim 25, wherein the number of surface mount technology device mounted to the flexible substrate equal the number of probe pins used for connecting to the corresponding test points on the test hardware.

27. A method of manufacturing a flex probe, comprising the steps of:
(a) designing a flex circuit based on data relating to a device to be tested;
(b) building the flex circuit having a flexible substrate, probe pads and probe lands, wherein each probe land extends for a probe pad;
(c) building a probe tip on each probe pad.

28. The method of claim 27, further comprising the steps of
(a) building a mechanical probe head; and
(b) attaching the flex circuit to the probe head.

29. The method of claim 27, wherein the probe tip is formed on the probe pad by plating.

30. The method of claim 27, wherein the probe tip is formed on the probe pad by evaporation.

31. A method for interfacing with a device under test, comprising the steps of:
(a) mating a conductive elastomeric layer attached to at least one probe pad on a flex circuit with a corresponding test point on a device under test; and
(b) adapting each probe land extending from a probe pad for connection with the testing equipment, whereby, the testing equipment may communicate with the device under test.

32. The method of claim 31, wherein step of connecting the flex circuit comprises the step of aligning each probe pad with a corresponding test point.

33. A method of manufacturing a flex probe, comprising:
(a) designing a flex circuit based on data relating to a device to be tested;
(b) building the flex circuit having a flexible substrate, probe pads and probe lands, wherein each probe land extends for a probe pad;
(c) attaching a conductive elastomeric layer to the probe pads of the flex circuit.

34. The method of claim 33, wherein the conductive elastomeric layer is attached to the probe pads with a clamp.

35. A method for interfacing with a device under test, comprising the steps of:
(a) mating a plurality of probe pins, wherein each probe pin is attached to a cantilever of a flex circuit device with a corresponding test point on a device under test; and
(b) adapting the flex circuit device for connection with the testing equipment, whereby, the testing equipment may communicate with the device under test.

36. A method for manufacturing a probe array, comprising the steps of:
(a) determining locations of probe pin receiving channels on a nonconductive stiffener layer based data relating to a device to be tested;
(b) forming the probe pin receiving channels on the nonconductive stiffener layer based on step (a);
(c) designing and building a flex circuit device with cantilevers based on requirements for spring force at each test point on the device to be tested;
(d) attaching the flex circuit to the nonconductive stiffener layer, such that a portion of each cantilever is extended over a probe pin receiving channel;
(e) placing probe pins in the probe pin receiving channels; and
(f) attaching probe pins to the portion of the cantilever extending over the probe pin receiving channel.

37. The method of claim 36, wherein further comprising the steps of screening and pasting to the flex circuit.

38. The method of claim 36, wherein the step of attaching the flex circuit to the nonconductive stiffener layer comprises the steps of:
(a) applying selectively an adhesive to the nonconductive stiffener layer; and
(b) aligning the flex circuit on the nonconductive stiffener layer, so that a portion of each cantilever formed in the flex circuit extends over a probe pin receiving channel;

39. The method of claim 38, wherein the step of aligning aligns a distal portion of the cantilever to extend over the probe pin receiving channel.

40. The method of claim 36, wherein the step of attaching a probe pin to a cantilever is accomplished by soldering the probe pin to a portion of the cantilever using a reflow solder process.

41. A method for interfacing with a device under test, comprising the steps of:
(a) mating a plurality of probe pins with corresponding test points on a device under test, wherein each probe pin is attached to a cantilever of a surface mount technology device that is electrically connected to a flex circuit by a conductive via; and
(b) adapting the flex circuit device for connection with the testing equipment, whereby, the testing equipment may communicate with the device under test.

42. A method for manufacturing a probe array, comprising the steps of:
(a) determining locations of probe pin receiving channels on each of two nonconductive stiffener layers based data relating to a device to be tested;
(b) forming the probe pin receiving channels on both nonconductive stiffener layer based on step (a);
(c) inserting probe pins into the probe pin receiving channels, thereby, aligning the two nonconductive stiffener layers;
(d) designing and building a flex circuit device with conductive vias for electrically connecting to a surface mount technology device;
(e) attaching the flex circuit to one of the two nonconductive stiffener layers;
(f) placing an surface mount technology device on the flex circuit such that it is in electrical communication with the flex circuit through a conductive via; and
(g) attaching a cantilever from each surface mount technology device to the probe pin.

43. A flex probe, comprising:
(a) a flexible circuit having at least one cantilever;
(b) the at least one cantilever having a probe tip.

44. The probe of claim 43, wherein the number of cantilevers formed in the flexible circuit equals the number of test points on a test hardware.

45. The probe of claim 43, wherein each of the probe tips are equal in height.

46. The probe of claim 43, wherein each of the probe tips has a pyramidal shape.

47. The probe of claim 43, wherein each of the probe tips has a conical shape. elastomeric layer to the flexible circuit.

48. A device testing interface for testing a fine pitched electronic assembly, the interface comprising:
(a) a non-conductive stiffener layer having at least one probe pin receiving channel corresponding to a test point location on a test hardware;
(b) a flexible circuit having a conductive layer, the flexible circuit device attached to the nonconductive stiffener layer; and
(c) a surface mount technology component with a conductive cantilever mounted on the flexible circuit.

49. The device of claim 48, further comprising a conductive via formed in the flexible circuit to electrically connect the surface mount technology component and the flexible circuit.

50. The device of claim 48, further comprising a probe pin in the probe pin receiving channel removably attached to the cantilever, whereby, the probe pin is electrically connected to the flexible circuit.

51. The device of claim 50, wherein the probe pin is a nail headed probe pin.
